(19) United States
(12) Patent Application Publication
(10) Pub. No.: US 2016/0131937 A1
(43) Pub. Date: May 12, 2016

(54) Display With Color Mixing Prevention Structures

(71) Applicant: Apple Inc., Cupertino, CA (US)

(72) Inventors: Young Cheol Yang, Sunnyvale, CA (US); Cheng Chen, San Jose, CA (US); Jong Won Lee, Paju-si, Gyeonggi-do (KR); Sung Ki Kim, Paju-si, Gyeonggi (KR); Jung ho Bang, Paju-si, Gyeonggi-do (KR); Jin bok Lee, Paju-si, Gyeonggi-do (KR); Seong Joo Lee, Paju-si, Gyeonggi-do (KR)

(21) Appl. No.: 14/897,079

(22) PCT Filed: Jun. 17, 2013
(86) PCT No.: PCT/US2013/046154

§ 371 Date: Dec. 9, 2015

(51) Int. Cl. G02F 1/1335; G02B 5/20; G03F 7/00; G02F 1/1368

(52) U.S. Cl. CPC G02F 1/133512; G02F 1/1368; G02F 1/133514; G02B 5/201; G03F 7/0007

(57) ABSTRACT

A display may be provided with a color filter layer. The display may have a thin-film transistor layer and a layer of liquid crystal material that is interposed between the color filter layer and the thin-film transistor layer. The color filter layer may include an array of color filter elements on a transparent substrate. The color filter elements may be formed from colored photoresist. An inorganic layer may be deposited on the color filter elements. An opaque matrix such a black matrix formed from black photoresist may be formed on the inorganic layer. The color photoresist color filter elements may be rectangular and may be arranged on the transparent substrate in a rectangular array. The black matrix may contain an array of rectangular openings. Each of the openings of the black matrix may be aligned with a corresponding one of the color filter elements.

### BACKGROUND

This relates generally to displays, and more particularly, to displays with color filter layers.

Electronic devices such as computers and handheld electronic devices have displays such as liquid crystal displays. A liquid crystal display typically has a rectangular central active area surrounded by a ring-shaped inactive area. An array of display pixels in the active area is used in displaying images for a user. A color filter layer formed from an array of color filter elements such as red, blue, and green color filter elements is used to provide the display with the ability to display color images. The color filter layer includes a black mask in the inactive area to form an opaque border and includes a grid-shaped black matrix in the active area.

In modern displays, there is a tendency to form arrays of color filter elements with increasingly fine pitches. Due to the relatively close proximity between display pixels of different colors in these displays, there is a potential for undesired color mixing effects in which light from pixels of one color pass through color filter elements associated with pixels of another color. Color mixing, which is sometimes referred to as color washout, reduces the ability of a display to accurately present color images to a user.

It would therefore be desirable be able to reduce color washout in displays with arrays of color filter elements.

### SUMMARY

A liquid crystal display may be provided with a color filter layer and a thin-film transistor layer. The color filter layer may have a glass substrate covered with color filter element structures. The thin-film transistor layer may have a glass substrate covered with thin-film transistor circuitry. A layer of liquid crystal material may be interposed between the color filter layer and the thin-film transistor layer. Upper and lower polarizer layers may be formed above and below the color filter layer and the thin-film transistor layer.

The display may have an active area with an array of display pixels. An inactive area may surround the active area. A black mask structure may be formed in the inactive area. A black matrix having a grid shape forming an array of rectangular openings may be formed in the active area. The color filter layer may have an array of red, green, and blue color filter elements that overlap the rectangular openings of the black matrix.

The color filter elements may be formed from colored photoresist. An inorganic buffer layer may be deposited on the color filter elements to prevent adhesion between black matrix material and the colored photoresist. The black matrix may be formed by depositing a layer of black photoresist on the inorganic layer and removing an array of rectangular portions of the black photoresist to form the array of rectangular openings in the active area.

Further features, their nature and various advantages will be more apparent from the accompanying drawings and the following detailed description of the preferred embodiments.

### BRIEF DESCRIPTION OF THE DRAWINGS

FIG. 1 is a schematic diagram of an electronic device of the type that may be provided with a display in accordance with an embodiment of the invention.

FIG. 2 is a diagram of an illustrative array of display pixels in a display in accordance with an embodiment of the present invention.

FIG. 3 is a cross-sectional side view of an illustrative display in accordance with an embodiment of the present invention.

FIG. 4 is a top view of a portion of a color filter layer for a display in accordance with an embodiment of the present invention.

FIG. 5 is a cross-sectional side view of a portion of a display showing how color filter layer structures may be formed in accordance with an embodiment of the present invention.

FIG. 6 is a cross-sectional side view of a color filter layer substrate that has been coated with a blanket red layer in accordance with an embodiment of the present invention.

FIG. 7 is a cross-sectional side view of the color filter layer substrate of FIG. 6 following patterning of the red layer to form an array of red color filter elements in accordance with an embodiment of the present invention.

FIG. 8 is a cross-sectional side view of the color filter layer substrate of FIG. 7 following deposition of a green layer over the patterned red color filter elements in accordance with an embodiment of the present invention.

FIG. 9 is a cross-sectional side view of the color filter layer substrate of FIG. 8 following patterning of the green layer to form an array of green color filter elements in accordance with an embodiment of the present invention.

FIG. 10 is a cross-sectional side view of the color filter layer substrate of FIG. 9 following deposition of a blue layer over the patterned red and green color filter elements in accordance with an embodiment of the present invention.

FIG. 11 is a cross-sectional side view of the color filter layer substrate of FIG. 10 following patterning of the blue layer to form an array of blue color filter elements in accordance with an embodiment of the present invention.

FIG. 12 is a cross-sectional side view of the color filter layer substrate of FIG. 11 following deposition of an inorganic buffer layer over the red, green, and blue color filter elements in accordance with an embodiment of the present invention.

FIG. 13 is a cross-sectional side view of the color filter layer substrate of FIG. 12 following deposition of a black layer in accordance with an embodiment of the present invention.

FIG. 14 is a cross-sectional side view of the color filter layer substrate of FIG. 13 following patterning of the black layer to form a black matrix structure separating the color filter elements of the color filter element array in accordance with an embodiment of the present invention.

FIG. 15 is a cross-sectional side view of an illustrative color filter layer formed by depositing a planarization layer over the structures of FIG. 14 in accordance with an embodiment of the present invention.

FIG. 16 is a diagram showing equipment that may be used in forming a display in accordance with an embodiment of the present invention.

FIG. 17 is a flow chart of illustrative steps involved in forming a display in accordance with an embodiment of the present invention.

### DETAILED DESCRIPTION

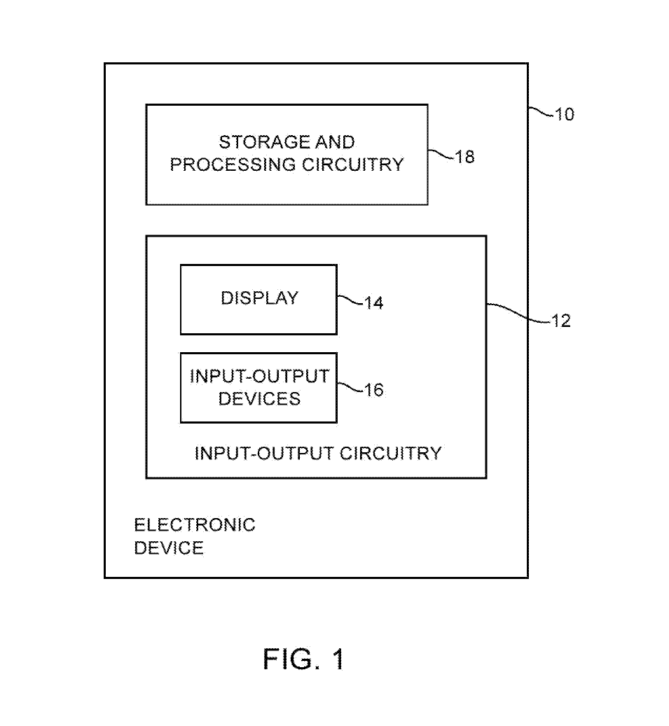

An illustrative electronic device of the type that may be provided with a display is shown in FIG. 1. Electronic devices such as illustrative electronic device 10 of FIG. 1 may be laptop computers, tablet computers, cellular telephones, media players, other handheld and portable electronic devices, smaller devices such as wrist-watch devices, pendant devices, headphone and earpiece devices, other wearable and miniature devices, or other electronic equipment.

As shown in FIG. 1, device 10 may include storage and processing circuitry 18 and input-output circuitry 12. Storage and processing circuitry 18 may include storage such as hard disk drive storage, nonvolatile memory (e.g., flash memory or other electrically-programmable-read-only memory configured to forma solid state drive), volatile memory (e.g., static or dynamic random-access-memory), etc. Processing circuitry in storage and processing circuitry 18 may be used to control the operation of device 10. This processing circuitry may be based on one or more microprocessors, microcontrollers, digital signal processors, application specific integrated circuits, etc.

Input-output circuitry 12 may be used to receive input from users and the environment and may be used to supply output to users and external equipment. Input-output circuitry 12 may include input-output devices 16 such buttons, joysticks, click wheels, scrolling wheels, touch pads, key pads, keyboards, microphones, cameras, buttons, speakers, status indicators, light sources, audio jacks and other audio port components, digital data port devices, light sensors, motion sensors (accelerometers), capacitance sensors, proximity sensors, wireless and wired communications circuitry, etc. Input-output circuitry 12 may also include displays such as display 14. Display 14 may be a touch screen display or may be a display that is insensitive to touch input. Examples of touch screen displays include displays that have arrays of capacitive touch sensor electrodes. Other types of touch sensor arrays may be incorporated into display 14 if desired.

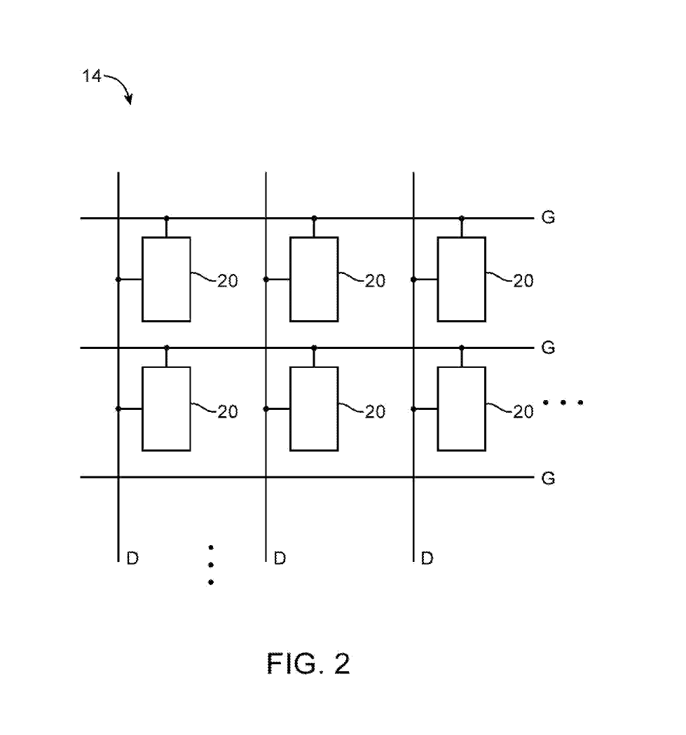

Display 14 may be a liquid crystal display having an array of display pixels such as display pixels 20 of FIG. 2. Each pixel 20 may have circuitry such as thin-film transistor circuitry, electrodes, and a storage capacitor for controlling electric fields that are applied to a corresponding portion of a liquid crystal layer. Gate lines G and data lines D may be used in distributing display control signals to display pixels 20.

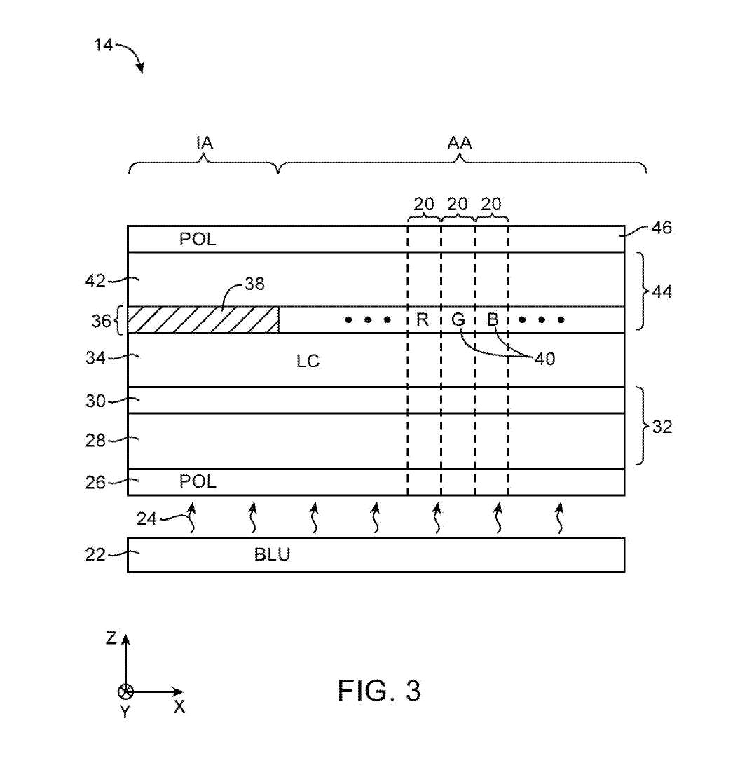

A cross-sectional side view of display 14 is shown in FIG. 3. Backlight unit 22 may be based on a fluorescent light bulb or an array of light-emitting diodes. Backlight unit 22 may produce backlight 24 that travels vertically through the display layers of display 14 in direction Z.

Display 14 includes lower polarizer 26 and upper polarizer 46. Display pixels 20 include electrodes and other thin-film transistor circuitry that control the electric field applied to liquid crystal layer 34. By controlling the electric field, the liquid crystal layer can control the polarization of light 24 in each display pixel as the light passes through liquid crystal layer 34, thereby controlling the brightness of each pixel 20.

Liquid crystal layer 34 is sandwiched between thin-film transistor layer 32 and color filter layer 44. Thin-film transistor layer 32 includes a clear substrate such as glass substrate 28 and a layer of thin-film transistor circuitry 30 (e.g., polysilicon and/or amorphous silicon transistors, pixel electrodes, gate lines and data lines, etc.).

Color filter layer 44 includes a clear substrate such as glass substrate 42. Display 14 may have a rectangular shape. A rectangular central region that is sometimes referred to as active area AA may contain a rectangular array of display pixels 20 and can be used to display images for a user. A rectangular ring-shaped inactive border region that is sometimes referred to as inactive area IA may surround active area AA. The left side of the inactive border region is shown in the cross-sectional side view of display 14 of FIG. 3.

Color filter layer 44 may include a layer of color filter structures 36 on substrate 42. In inactive area IA, color filter structures 36 may include a strip of opaque masking material such as black masking material 38 that forms an opaque border called a black mask. In active area AA, color filter structures 36 may include an array of color filter elements 40. The materials that are used in forming black masking material 38 and color filter elements 40 may be polymers (i.e., photoresist that includes a black material such as carbon black or a metal complex or other black photoresist for material 38 and colored photoresist such as red, green, and blue photoresist formed from colored pigments or dyes for color filter elements 40).

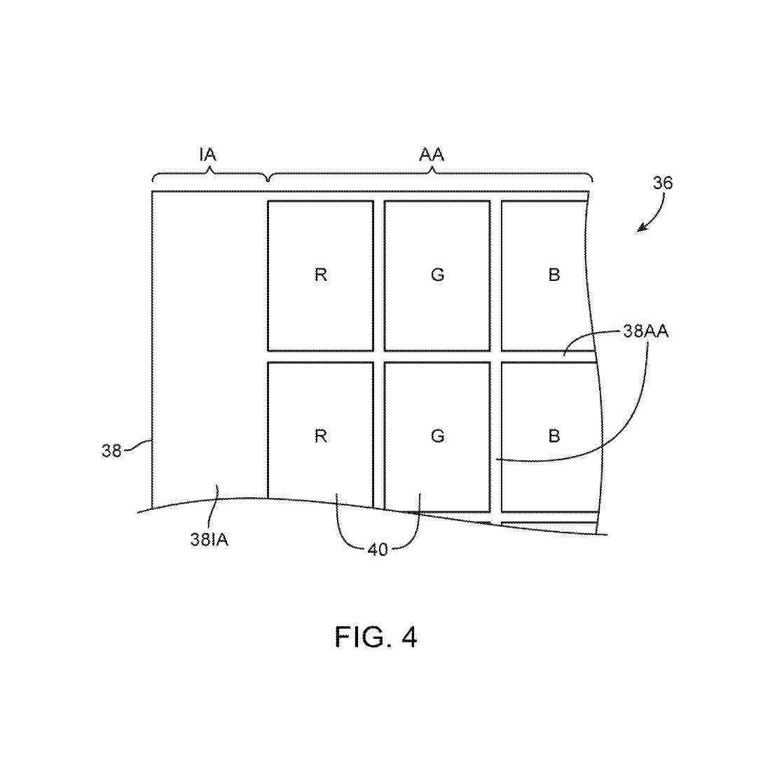

FIG. 4 is a top view of an illustrative portion of color filter layer structures 36 in color filter layer 44. In inactive region IA, black masking material 38 may be used in forming an opaque border structure such as black mask 38IA. In active region AA, color filter elements 40 such as red (R), green (G), and blue (B) filter elements may be organized in an array having rows and columns of elements. Portions of black masking material 38 may be used in forming an opaque grid between respective color filter elements to help reduce color bleeding between adjacent pixels. The opaque grid formed using black masking material 38 may sometimes be referred to as a black matrix or opaque matrix.

As shown in FIG. 4, black matrix 38AA may forma grid with a series of rectangular openings each of which is overlapped by a respective color filter element 40 (i.e., each color filter element is aligned with and therefore overlaps a respective one of the rectangular openings so that a respective color is imparted to the light passing through that color filter element).

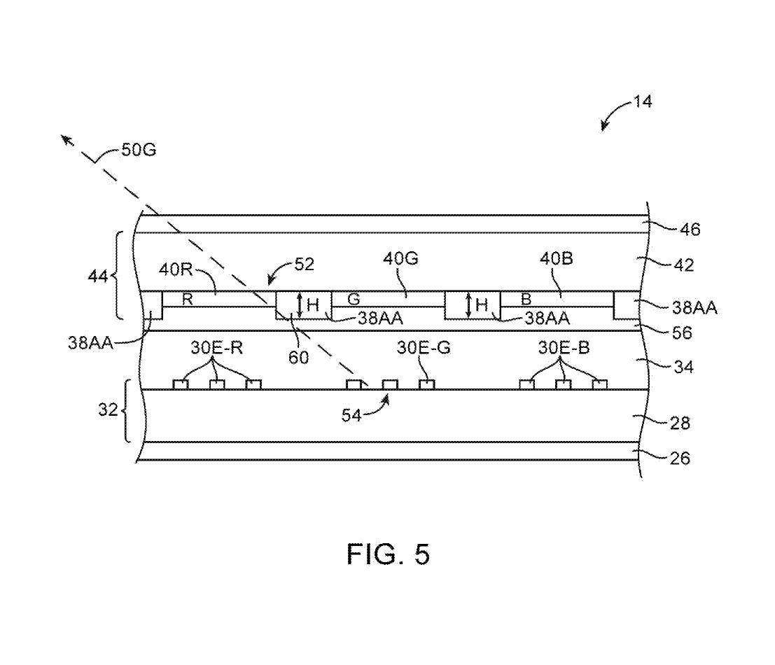

A cross-sectional side view of a portion of display 14 is shown in FIG. 5. As shown in FIG. 5, liquid crystal layer 34 may be sandwiched between color filter layer 44 and thin-film transistor layer 32. Upper polarizer 46 may be formed on color filter layer 42. Lower polarizer 26 may be formed on the lower surface of thin-film transistor layer 32. Other layers may be incorporated into display 14 if desired (e.g., antireflection coating layers, anti-smudge layers, shielding layers, etc.).

Thin-film transistor layer 32 may include metal display pixel electrodes 30E on glass substrate 28. Electrodes 30E are associated with display pixels 20 and are used in applying an adjustable electric field to an associated overlapping portion of liquid crystal layer 34.

Black (opaque) matrix 38AA may be formed from a grid of opaque material such as black masking material 38. Clear overcoat layer 56 may be applied over color filter elements such a red color filter elements 40R, green color filter elements 40G, and blue color filter elements 40B and over black matrix 38AA and may serve as a planarization layer. Thin-film transistor circuitry may be formed on thin-film transistor substrate 28 in thin-film transistor layer 32. The thin-film transistor circuitry may include electrodes for the display pixels in display 14. As shown in FIG. 5, the electrodes may include red pixel electrodes 30E-R in red pixels, green pixel electrodes 30E-G in green pixels, and blue pixel electrodes 30E-B in blue pixels. Red pixel electrodes 30E-R are aligned with corresponding red color filter elements 40R, green pixel electrodes 30E-G are aligned with corresponding green color filter elements 40G, and blue pixel electrodes 30E-B are aligned with corresponding blue color filter elements 40B.

Due to misalignment between the electrodes and the color filter elements and/or due to the presence of off-axis (non-vertical) backlight 24 from backlight unit 22, there is a potential for undesired color washout in liquid crystal displays with arrays of color filter elements. Color washout occurs when a ray of backlight such as illustrative ray 50G that is passing through an “ON” pixel (e.g., the green pixel in the example of FIG. 5) does not pass through its associated color filter element, but rather passes through the color filter element of a differently colored adjacent pixel.

In the example of FIG. 5, rays of white light from backlight unit 22 that pass through the “ON” liquid crystal material in the vicinity of green pixel electrode 30E-G should be passing through the green color filter element 40G that is associated with electrode 30E-G to impart a green color to the backlight so that viewer 60 will observe the light as being of the correct color (i.e., green in this example). Due to misalignment and/or off-axis propagation, light ray 50G may potentially pass through red pixel 40R as shown in FIG. 5, leading to a color washout condition in which green image data erroneously appears red. Color washout (color mixing) between adjacent pixels of other colors is also possible. The use of an ON green pixel to produce light that potentially passes through an adjacent red color filter element illustrates the color washout issue.

To minimize the potential for image degradation due to color washout, the structures that make up black matrix 38AA may be provided with an enhanced thickness (height) H. The thickness that is used for a given display may be selected to minimize color washout while avoiding excessive thickness that could lead to processing issues. In general, the thickness H of black matrix 38AA in the active area of display 14 may be 50 nm to 10,000 nm (as an example). As shown in FIG. 5, when black matrix 38AA is sufficiently thick, portions of black matrix 38AA such as illustrative portion 60 will intercept and therefore block errant light rays such as illustrative light ray 50G of FIG. 5. By blocking ray 50G with portion 60 of black matrix 38AA, ray 50G will be prevented from passing through portion 52 of red color filter element 40R, thereby reducing color mixing.

In order to produce black matrix structures that protrude sufficiently from the lower surface of glass substrate 42 in color filter layer 44, it may be desirable to form black matrix 38AA after forming the array of color filter elements 40 on glass substrate 42. In this way, the outermost surfaces of black matrix 38AA can protrude further outward than the exposed surfaces of color filter elements 40 (which do not need to be as thick). Cross-sectional side views of color filter layer structures during various steps involved in forming color filter layer 44 using this type of approach are shown in FIGS. 6, 7, 8, 9, 10, 11, 12, 13, 14, and 15.

Initially, a color filter layer such as blanket red color filter layer 40RB may be deposited on color filter substrate 42, as shown in FIG. 6. Red color filter layer 40RB may be formed from a photoimageable polymer such as red photoresist. Dye, pigments, or other materials may be used in imparting colors such as a red color to the color filter elements. Layer 40RM may, for example, be formed from photoresist that includes a red dye or a red pigment.

Photolithographic patterning may be used to pattern red photoresist layer 40RB to form red color filter elements 40R (i.e., red photoresist color filter elements), as shown in FIG. 7.

Following formation of the red color filter elements 40R, a blanket layer of green photoimageable material such as green photoresist 40GB may be deposited on the surface of color filter layer substrate 42, as shown in FIG. 8. Green photoresist layer 40GB may cover the red color filter elements.

Following deposition of green photoresist layer 40GB, green photoresist layer 40GB may be patterned to form an array of green color filter elements 40G, as shown in FIG. 9.

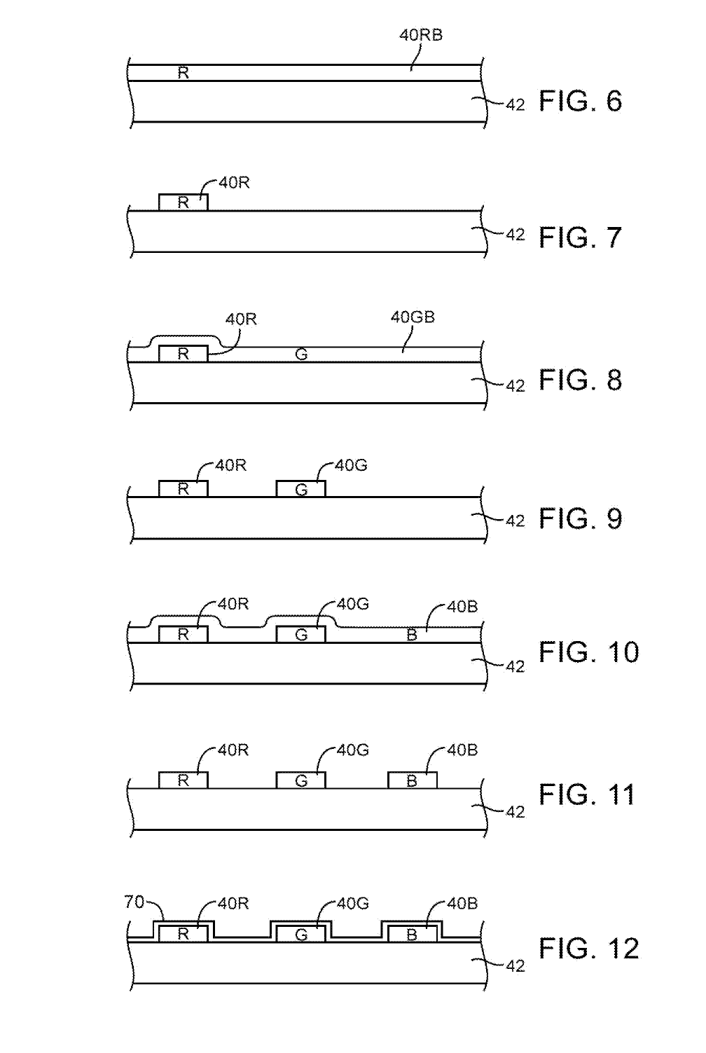

FIG. 10 shows how a blanket layer of blue photoimageable material such as blue photoresist layer 40BB may be deposited on substrate 42 after the green color filter elements 40G have been formed. Blue photoresist layer 40BB may cover red color filter elements 40R and green color filter elements 40G.

Photolithographic patterning may be used to pattern blue photoresist layer 40BB to form blue color filter elements 40B, as shown in FIG. 11. Red color filter elements 40R, green color filter elements 40G, and blue color filter elements 40B may be arranged in a rectangular array of color filter elements 40, as shown in FIG. 4.

Following formation of the array of color filter elements on substrate 42, buffer layer 70 may be deposited, as shown in FIG. 12. Buffer layer 70 may be formed from an inorganic material such as silicon oxide, silicon nitride, other inorganic substance that contain silicon, oxygen, and/or nitrogen, etc. or other substance that helps prevent subsequently deposited black masking material from interacting with the colored photoresist of color filter elements 40R, 40G, and 40B. The buffer layer may have a thickness in the range of 40 angstroms to 5000 angstroms (as an example). Thicknesses of more or less than 40-5000 angstroms may also be used, if desired. Inorganic layer 70 may be deposited as a blanket film that covers the surfaces of color filter elements 40 (e.g., by using sputtering or other deposition techniques).

Black masking material 38 may be formed from a material such as photoresist that includes carbon black, metal compounds, or other material that renders masking material 38 opaque to visible light. In scenarios in which masking material 38 is formed from a material such as photoresist that is similar or identical to the material of color filter elements 40 (i.e., photoresist), there is a potential that chemical bonds may form between the color filter elements and masking material 38. This can make it difficult or impossible to completely remove deposited masking material from color filter elements using photolithographic patterning. Black masking material residue that remains on the color filter elements after black matrix formation can degrade display performance by scattering and absorbing light that is passing through the color filter elements so that the display appears undesirably dim.

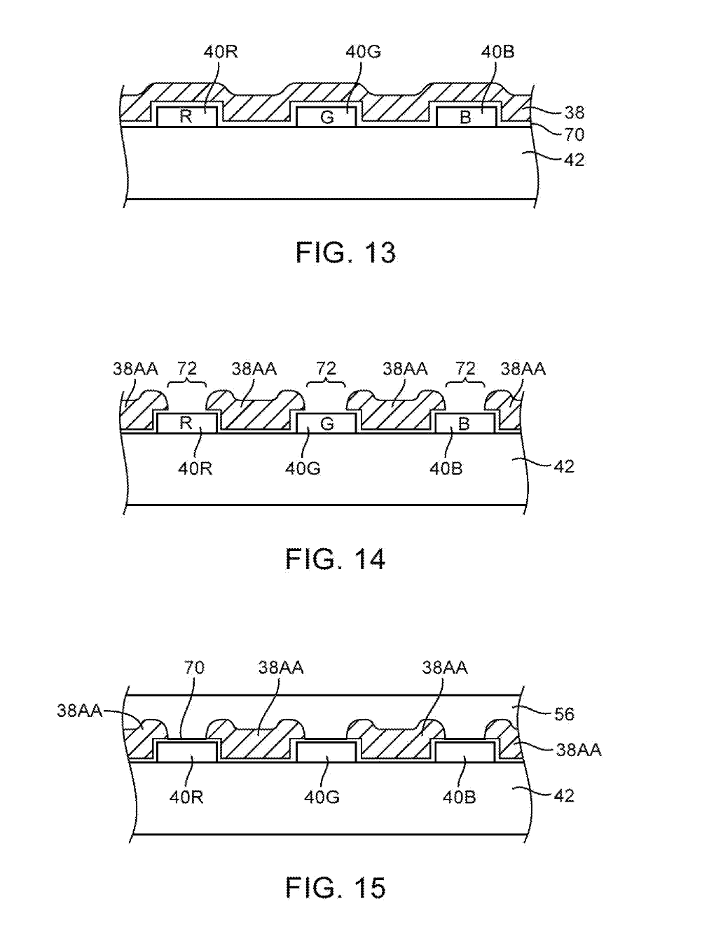

By covering the surfaces of color filter elements 40 with an inorganic buffer layer such as inorganic buffer layer 70 of FIG. 12, the tendency of black masking layer material to form a residue on color filter elements 40 may be reduced. As shown in FIG. 13, black masking layer material 38 may be deposited in the form of a blanket layer covering buffer layer 70 and covering the underlying array of color filter elements 40R, 40G, and 40B. Buffer layer 70 is interposed between the surfaces of each color filter element and the black masking material of layer 38 to facilitate complete (residue free) removal of portions of layer 38 during photolithographic patterning.

As shown in FIG. 14, for example, black masking material 38 may be removed in regions 72 to expose central rectangular portions 72 of the surfaces of color filter elements 40R, 40G, and 40B and thereby form black matrix 38AA. The black organic photoresist material of layer 38 does not interact significantly with inorganic buffer layer 70, so during patterning of the photoresist, the photoresist can be removed completely from regions 72 without leaving any photoresist residue (i.e., rectangular portions of the photoresist can be removed to produce rectangular openings that are free of photoresist residue on inorganic buffer layer 70).

Following patterning of black masking layer 38 to form grid-shaped black matrix 38AA of FIG. 14, a clear organic overcoat layer such as overcoat layer 56 may be deposited on color filter substrate 42 over color filter elements 40R, 40G, and 40B, over buffer layer 70, and over black matrix 38AA. Overcoat layer 56 may be formed from a material such as a clear polymer and may serve as a planarization layer.

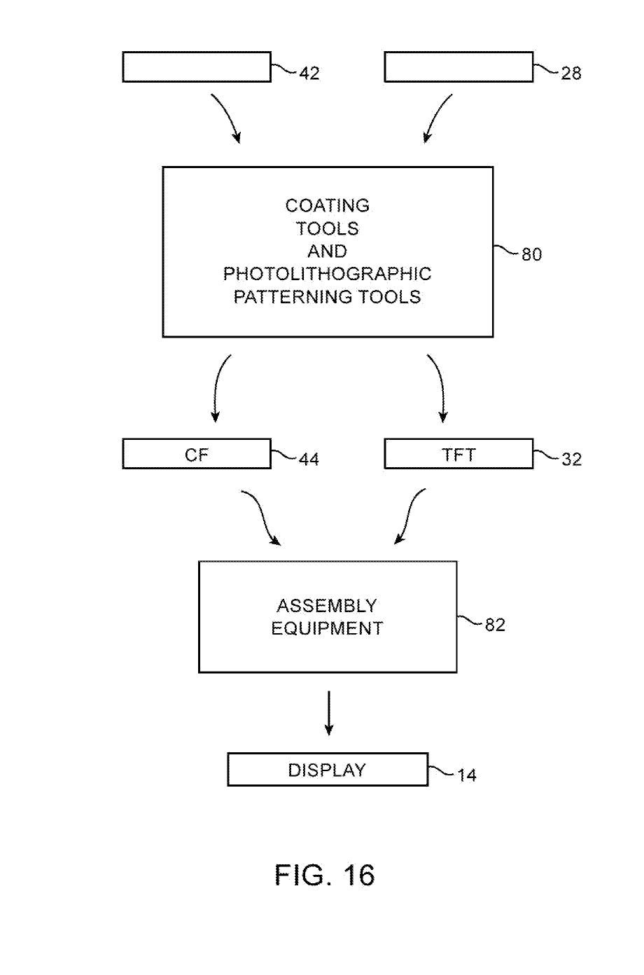

Illustrative equipment for forming display 14 is shown in FIG. 16. As shown in FIG. 16, coating tools and photolithographic patterning tools 80 or other fabrication equipment may be used in depositing blanket layers of material on the substrate layers of display 14 and may be used in patterning the deposited layers to form color filter elements, buffer layer material, opaque matrix material, thin-film-transistor electrodes and other thin-film transistor circuitry, etc.

Tools 80 may receive substrate layers such a layers of glass or plastic and may deposit and pattern layers of material on top of the substrate layers. For example, tools 80 may deposit patterned coating layers on color filter substrate 42 to form color filter layer 44 and may deposit patterned layers for electrodes and other circuitry on thin-film-transistor substrate 28 to form thin-film-transistor layer 32.

Assembly equipment 82 may include computer-controlled positioners and/or manually operated equipment for assembling display layers such as color filter layer 44 and thin-film-transistor layer 32 and other structures (e.g., liquid crystal material, polarizers, etc.) to form display 14.

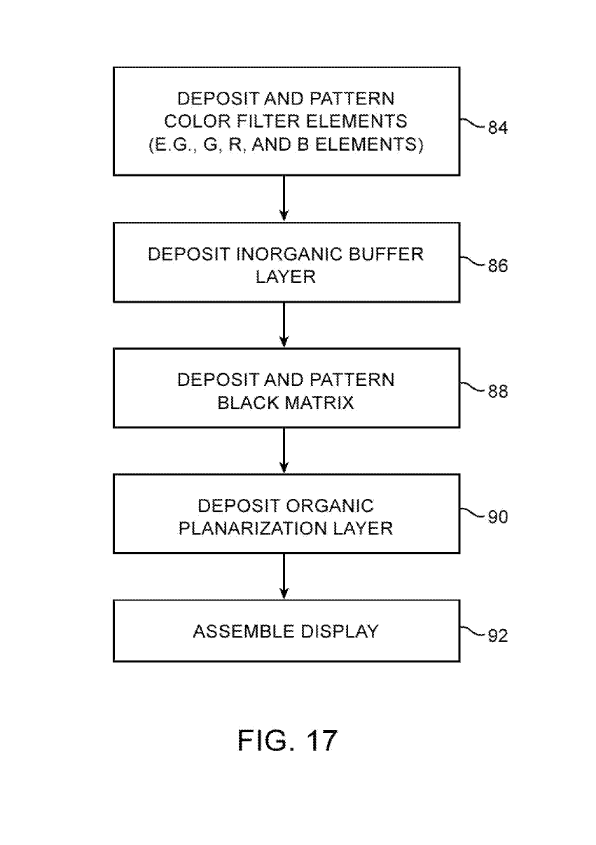

Illustrative steps involved in forming display 14 are shown in FIG. 17.

At step 84, equipment such as tools 80 of FIG. 16 may be used to pattern color filter elements 40 onto color filter substrate 42. Color filter elements 40 may be formed by depositing and photolithographically patterning colored photoresist such as red, green, and blue photoresist. The color filter elements may be arranged in an array pattern on the surface of color filter substrate 42.

At step 86, equipment such as tools 80 may be used to deposit a layer that facilitates removal of black masking material that is subsequently deposited over the color filter elements. In particular, tools 80 may deposit a buffer layer formed from an inorganic material such as inorganic buffer layer 70. Buffer layer 70 may cover the red, green, and blue color filter elements on the surface of the color filter layer substrate. The inorganic material of buffer layer 70 may be silicon oxide, silicon nitride, or other material that resists chemical bonding with photoresist.

At step 88, fabrication equipment such as tools 80 may be used to deposit opaque masking material such as black photoresist. The black photoresist or other black masking material may be deposited as a blanket film on inorganic buffer layer 70 on the surface of color filter layer substrate 42. In depositing the black photoresist, the black photoresist may cover the red, green, and blue color filter elements that lie under the inorganic buffer layer. Following black photoresist deposition, the buffer layer is interposed between the color filter elements and the black photoresist to help prevent the black photoresist from adhering to the color filter elements and leaving black photoresist residue that could degrade display performance. The black photoresist may be patterned to form black matrix 38AA using photolithographic patterning techniques. The photolithographic patterning techniques remove portions of the black photoresist in the regions overlapping the color filter elements (see, e.g., regions 72 of FIG. 14). Because of the presence of buffer layer 70, the black photoresist in regions 72 may be removed cleaning without leaving a black photoresist residue that might degrade display performance.

At step 90, planarization overcoat layer 56 may be deposited over black matrix 38AA and the other structures on the surface of color filter substrate 42 to form color filter layer 44.

At step 92, color filter layer 44 may be assembled with other display structures such as thin-film transistor layer 32 to form display 14.

The foregoing is merely illustrative of the principles of this invention and various modifications can be made by those skilled in the art without departing from the scope and spirit of the invention. The foregoing embodiments may be implemented individually or in any combination.

What is claimed is:

1. A display, comprising:
a thin-film transistor layer;
a color filter layer substrate;
a layer of liquid crystal material interposed between the thin-film transistor layer and the color filter layer substrate;
a black matrix, wherein the black matrix has openings;
an array of color filter elements on the color filter layer substrate each of which is aligned with a respective one of the openings; and
a buffer layer interposed between the array of color filter elements and the black matrix.

2. The display defined in claim 1 wherein the buffer layer comprises an inorganic buffer layer.

3. The display defined in claim 2 wherein the inorganic buffer layer has a thickness of 40 angstroms to 4000 angstroms.

4. The display defined in claim 3 wherein the black matrix comprises black photoresist on the inorganic buffer layer.

5. The display defined in claim 4 wherein the array of color filter elements comprises colored photoresist.

6. The display defined in claim 5 wherein the colored photoresist comprises red photoresist, green photoresist, and blue photoresist.

7. The display defined in claim 1 wherein the black matrix comprises black photoresist, wherein the array of color filter elements comprises a rectangular array of photoresist color filter elements including red color filter elements, green color filter elements, and a blue color filter elements and wherein the buffer layer comprises an inorganic layer interposed between the black photoresist and the photoresist color filter elements.

8. A display, comprising:
an opaque photoresist matrix having openings;
an array of color filter elements of different colors, wherein each of the color filter elements is aligned with a respective one of the openings; and
an inorganic layer that covers the array of color filter elements and that is interposed between the opaque photoresist matrix and the array of color filter elements.

9. The display defined in claim 8 wherein the inorganic layer comprises silicon.

10. The display defined in claim 9 wherein the inorganic layer is formed from a material selected from the group consisting of: silicon oxide and silicon nitride.

11. The display defined in claim 8 wherein the opaque photoresist comprises black photoresist.

12. The display defined in claim 11 wherein the color filter elements comprise red photoresist elements, green photoresist elements, and blue photoresist elements.

13. The display defined in claim 12 further comprising:
a thin-film transistor layer having electrodes; and
a liquid crystal layer between the thin-film transistor layer and the array of color filter elements.

14. A method of forming a display, comprising:
forming an array of color filter elements on a color filter layer substrate;
depositing an inorganic buffer layer over the array of color filter elements; and
forming an opaque matrix over the inorganic buffer layer, wherein the opaque matrix comprises openings that are each aligned with a respective one of the color filter elements.

15. The method defined in claim 14 wherein forming the array of color filter elements comprises forming colored photoresist elements.

16. The method defined in claim 15 wherein forming the opaque matrix comprises forming a black photoresist matrix.

17. The method defined in claim 16 wherein forming the colored photoresist elements comprises forming rectangular red photoresist elements, forming rectangular blue photoresist elements, and forming rectangular green photoresist elements.

18. The method defined in claim 17 wherein forming the inorganic buffer layer comprises forming an inorganic layer selected from the group consisting of: a silicon oxide layer and a silicon nitride layer.

19. The method defined in claim 14 wherein forming the opaque matrix comprises patterning black photoresist to form a grid with rectangular openings, wherein each color filter element in the array of color filter elements overlaps a respective one of the rectangular openings.

20. The method defined in claim 14 wherein the openings of the black matrix comprise rectangular openings and wherein forming the opaque matrix comprises:
depositing a layer of black photoresist on the inorganic buffer layer; and
removing rectangular portions of the black photoresist from the inorganic buffer layer to form the rectangular openings that are free of black photoresist residue on the inorganic buffer layer.
